(19) United States
(12) Patent Application Publication
(10) Pub. No.: US 2001/0014483 A1
(43) Pub. Date: Aug. 16, 2001

(54) METHOD OF FORMING A GATE OXIDE LAYER

(76) Inventors: HSUEH-HAO SHIH, HSINCHU (TW); JUAN-YUAN WU, HSINCHU (TW); WATER LUR, TAIPEI (TW)

Correspondence Address: J C Patents Inc, 1340 Reynolds Avenue, Suite 114, Irvine, CA, 92614, US

(21) Appl. No.: 09/199,707

(22) Filed: Nov. 24, 1998

(51) Int. Cl. H01L 21/00

(52) U.S. Cl. 438/2

(57) ABSTRACT

A method of forming a gate oxide layer according to the invention is disclosed. In the method, a furnace or rapid thermal oxidation (RTO) chamber where a semiconductor substrate having a native oxide layer formed thereon is located is supplied with a high-temperature hydrogen gas to deoxidize the native oxide layer. Then, a gate oxide layer is formed over the semiconductor substrate. The semiconductor substrate having the gate oxide layer formed thereon is transferred through a vacuum transmission system into a reaction chamber where a polysilicon layer is formed on the gate oxide layer. Thus, the semiconductor substrate can avoid exposure to an oxygen-containing atmosphere to re-form a native oxide layer thereon.

### BACKGROUND OF THE INVENTION

1. Field of the Invention

The invention relates to a method of forming a semiconductor device, and in particular to a method of forming a high-quality gate oxide layer by deoxidizing a native oxide.

2. Description of the Related Art

In very large semiconductor integration (VLSI) process, the thickness of a gate oxide layer of an MOS (Metal Oxide Semiconductor) device is approximately 100-200Å. For a high-level device, such as a flash memory, the thickness of a tunneling oxide layer is less than 100Å, even approximately 30Å. Thus, it is very difficult to form a high-quality gate oxide layer with such a thin thickness. In addition to the problem of uneasy controlling the quality of a gate oxide layer formed with such a thin thickness, it has to overcome influences brought by a native oxide layer with a thickness of approximately 2-10Å which still remains after a pre-cleaning step and before the formation of the gate oxide layer.

It is well-known that when a silicon wafer is exposed to an oxygen-containing atmosphere, such as an oxygen or a water atmosphere, the surface of the silicon wafer is oxidized to form a silicon dioxide layer, called a native oxide layer, thereon. That is, under this circumstance, oxygen molecules can reach the surface of the silicon wafer through a boundary layer in a thermal diffusion effect to react with silicon atoms, thereby producing the silicon dioxide layer thereon. After that, subsequent oxidation becomes more difficult since reaction-participating oxygen molecules must first reach the surface of the silicon dioxide layer, and then diffuse therein onto the surface of the silicon wafer for oxidation. In other words, the reaction-participating oxygen molecules cannot directly reach on the surface of the silicon wafer for oxidation. Furthermore, the native oxide layer with a poor uniformity can affect the quality of a subsequently formed gate oxide layer. Therefore, how to avoid the formation of the native oxide layer or eliminate the native oxide layer becomes a very important issue.

Moreover, a gate oxide layer is formed beneath the native oxide layer, such that when a patterned polysilicon layer, serving as a gate structure, is formed on the native oxide layer, water molecules adhere to the native oxide layer, lowering the reliability of the gate structure.

### SUMMARY OF THE INVENTION

In view of the above, an object of the invention is to provide a method of forming a gate oxide layer by deoxidizing a native oxide layer. Thus, problems of a poor uniformity on the gate oxide layer and a poor reliability in subsequent processes can be completely prevented.

To achieve the above-stated object, a method of forming a gate oxide layer according to the invention is provided. In the method, a furnace or rapid thermal oxidation (RTO) chamber where a semiconductor substrate having a native oxide layer formed thereon is located is supplied with a high-temperature hydrogen gas to deoxidize the native oxide layer. Then, a gate oxide layer is formed over the semiconductor substrate. The semiconductor substrate having the gate oxide layer formed thereon is transferred through a vacuum transmission system into a reaction chamber where a polysilicon layer is formed on the gate oxide layer. Thus, the semiconductor substrate can avoid exposure to an oxygen-containing atmosphere to re-form a native oxide layer thereon.

Additionally, to achieve the above-stated object, a method of forming a gate oxide layer according to the invention is provided. In the method, a semiconductor substrate already having a native oxide layer formed thereon is oxidized to form a gate oxide layer beneath the native oxide layer. In the same system, the native oxide layer is deoxidized by supplying a high-temperature hydrogen gas. Next, the semiconductor substrate having the gate oxide layer formed thereon is transferred to a reaction chamber through a vacuum transmission system for the formation of a polysilicon gate. Thus, the semiconductor substrate can avoid exposure to an oxygen-containing atmosphere to re-form a native oxide layer thereon.

### BRIEF DESCRIPTION OF THE DRAWINGS

The invention will become more fully understood from the detailed description given hereinbelow and the accompanying drawings which are given by way of illustration only, and thus do not limit the present invention, and wherein:

FIGS. 1A-1C are schematic, cross-sectional views showing a method of forming a gate oxide layer after deoxidizing a native oxide layer according to a first preferred embodiment of the invention; and

FIGS. 2A-2D are schematic, cross-sectional views showing a method of forming a gate oxide layer before deoxidizing a native oxide layer according to a second preferred embodiment of the invention.

### DETAILED DESCRIPTION OF THE PREFERRED EMBODIMENTS

### Embodiment 1

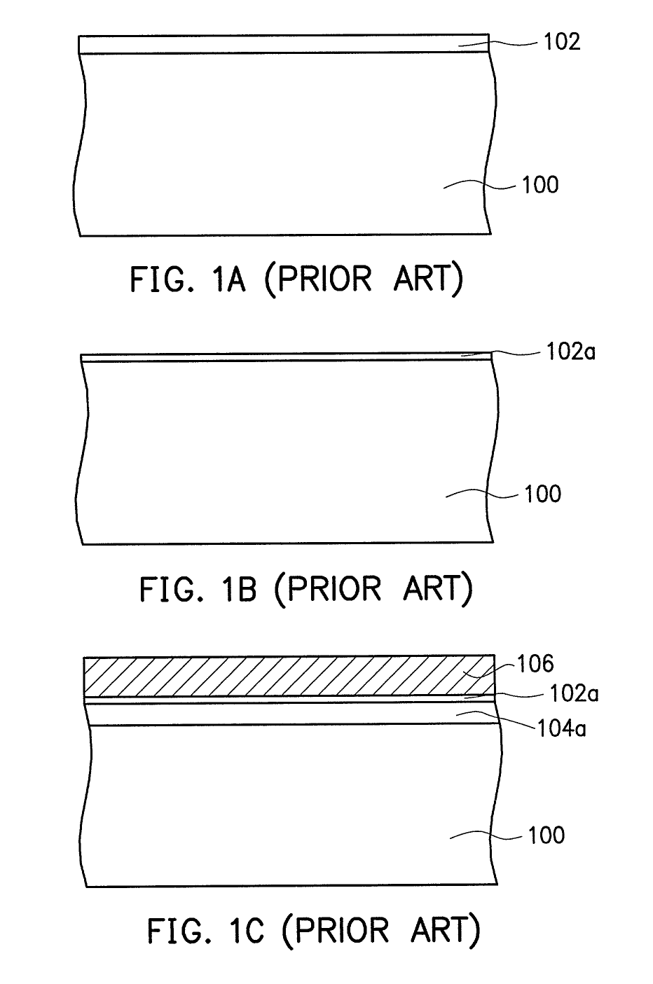

FIGS. 1A-1C are schematic cross-sectional views showing a method of forming a gate oxide layer after deoxidizing a native oxide layer according to a first preferred embodiment of the invention.

Referring to FIG. 1A, a semiconductor substrate 100 is first rinsed so as to remove impurities and part of a native oxide layer (not shown) naturally formed thereon in an oxygen-containing atmosphere. After that, a native oxide layer 102 with a thickness of approximately 2-10Å remains on the semiconductor substrate 100.

Referring to FIG. 1B, the semiconductor substrate 100 is sent into, for example, a furnace, which is supplied with a high-temperature hydrogen gas having a temperature of approximately 750-900° C. and a flow of 0.5-5 sccm. With the high-temperature hydrogen gas, the native oxide layer 102 is partly deoxidized to form a remaining native oxide layer 102a, or even completely deoxidized.

Referring to FIG. 1C, a gate oxide layer 104a with a thickness of approximately 30Å is formed between the semiconductor substrate 100 and the remaining native oxide layer 102a in, for example, a rapid thermal oxidation (RTO) chamber, a furnace or the like. The semiconductor substrate 100 with the gate oxide layer 104a and the remaining native oxide layer 102a formed thereon is transferred through a vacuum transmission system into a reaction chamber with a pressure of less than 30 Torr and a nitrogen gas supplied so as to subsequently form a polysilicon layer 106 on the remaining native oxide layer 102a. Thus, the semiconductor substrate 100 can avoid exposure to an oxygen-containing atmosphere to re-form a native oxide layer thereon. After the formation of the polysilicon layer 106, the polysilicon layer 106 is patterned to form a polysilicon gate (not shown) by photolithography and etching.

### Embodiment 2

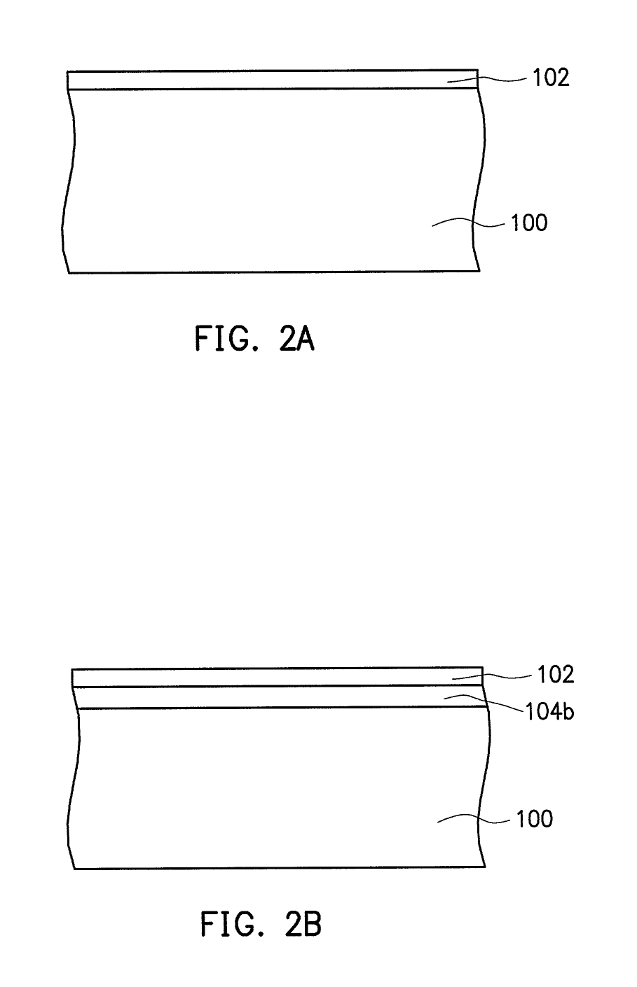

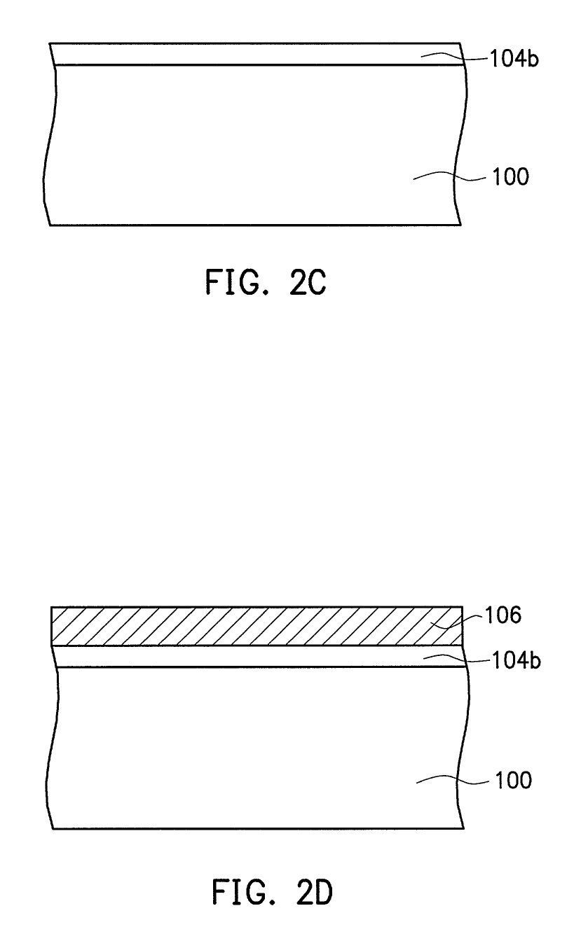

FIGS. 2A-2D are schematic, cross-sectional views showing a method of forming a gate oxide layer before deoxidizing a native oxide layer according to a second preferred embodiment of the invention.

Referring to FIG. 2A, a semiconductor substrate 100 is first rinsed so as to remove impurities and part of a native oxide layer (not shown) naturally formed thereon in an oxygen-containing atmosphere. After that, a native oxide layer 102 with a thickness of approximately 2-10Å remains on the semiconductor substrate 100.

Referring to FIG. 2B, a gate oxide layer 104b with a thickness of approximately 30Å is formed between the substrate 100 and the native oxide layer 102 in, for example, a rapid thermal oxidation chamber, a furnace or the like.

Referring to FIG. 2C, the semiconductor substrate is sent into, for example, a furnace, which is supplied with a high-temperature hydrogen gas having a temperature of approximately 750-900° C. and a flow of 0.5-5 sccm. With the high-temperature hydrogen gas, the native oxide layer 102 is completely deoxidized (or partly deoxidized).

Referring to FIG. 2D, the semiconductor substrate 100 with the gate oxide layer 104b formed thereon is transferred through a vacuum transmission system into a reaction chamber with a pressure of 30 Torr and a nitrogen gas supplied for subsequently forming a polysilicon layer 106 on the gate oxide layer 104b. Thus, the semiconductor substrate 100 can avoid exposure to an oxygen-containing atmosphere to re-form a native oxide layer thereon. After the formation of the polysilicon layer 106, the polysilicon layer 106 is patterned to form a polysilicon gate (not shown) by photolithography and etching.

Accordingly, a main feature of the invention is that a native oxide layer formed on a semiconductor substrate is partly or completely deoxidized with a high-temperature hydrogen gas. As a result, a poor uniformity on a gate oxide layer or a poor quality thereof caused by the native oxide layer can be efficiently prevented.

While the invention has been described by way of example and in terms of the preferred embodiment, it is to be understood that the invention is not limited to the disclosed embodiments. To the contrary, it is intended to cover various modifications and similar arrangements as would be apparent to those skilled in the art. Therefore, the scope of the appended claims should be accorded the broadest interpretation so as to encompass all such modifications and similar arrangements.

What is claimed is:

1. A method of forming a gate oxide layer comprising the steps of:
providing a semiconductor substrate having a native oxide layer formed thereon;
deoxidizing the native oxide layer;
forming a gate oxide layer over the semiconductor substrate; and
forming a polysilicon layer on the gate oxide layer.

2. The method of forming a gate oxide layer as claimed in claim 1, wherein the thickness of the native oxide layer is approximately 2-10Å.

3. The method of forming a gate oxide layer as claimed in claim 1, wherein the step of deoxidizing the native oxide layer is performed in the presence of a hydrogen gas.

4. The method of forming a gate oxide layer as claimed in claim 3, wherein the hydrogen gas has a temperature of approximately 750-900° C. and a flow of approximately 0.5-5 sccm.

5. The method of forming a gate oxide layer as claimed in claim 1, wherein the thickness of the gate oxide layer is approximately 30Å.

6. The method of forming a gate oxide layer as claimed in claim 1, wherein the step of forming the gate oxide layer is performed by rapid thermal oxidation.

7. The method of forming a gate oxide layer as claimed in claim 1, wherein the step of forming the gate oxide layer is performed in a furnace.

8. A method of forming a gate oxide layer comprising:
providing a semiconductor substrate having a native oxide layer formed thereon;
forming a gate oxide layer between the semiconductor substrate and the native oxide layer;
deoxidizing the native oxide layer; and
forming a polysilicon layer on the gate oxide layer.

9. The method of forming a gate oxide layer as claimed in claim 8, wherein the thickness of the native oxide layer is approximately 2-10Å.

10. The method of forming a gate oxide layer as claimed in claim 8, wherein the step of deoxidizing the native oxide layer is performed in the presence of a hydrogen gas.

11. The method of forming a gate oxide layer as claimed in claim 10, wherein the hydrogen gas has a temperature of approximately 750-900° C. and a flow of approximately 0.5-5 sccm.

12. The method of forming a gate oxide layer as claimed in claim 8, wherein the thickness of the gate oxide layer is approximately 30Å.

13. The method of forming a gate oxide layer as claimed in claim 8, wherein the gate oxide layer is performed by rapid thermal oxidation.

14. The method of forming a gate oxide layer as claimed in claim 8, wherein the step of forming the gate oxide layer is performed in a furnace.
